(19) United States
(12) Patent Application Publication
(10) Pub. No.: US 2025/0120094 A1
(43) Pub. Date: Apr. 10, 2025

(54) MEMORY DEVICE HAVING REDUCED CIRCUIT AREA

(71) Applicant: UNITED MICROELECTRONICS CORP., Hsin-Chu City (TW)

(72) Inventors: Yan-Jou Chen, Yunlin County (TW); Chien-Yu Ko, Tainan City (TW); Cheng-Tung Huang, Kaohsiung City (TW)

(73) Assignee: UNITED MICROELECTRONICS CORP., Hsin-Chu City (TW)

(21) Appl. No.: 18/504,143

(22) Filed: Nov. 7, 2023

(30) Foreign Application Priority Data
Oct. 4, 2023 (TW) 112138094

(51) Int. Cl. H10B 61/00

(52) U.S. Cl. CPC H10B 61/22

(57) ABSTRACT

A memory device includes a first memory cell, a second memory cell, a word line, a bit line, a first source line and a second source line. The first memory cell includes a control terminal, a data terminal and a source terminal. The first memory cell includes a control terminal, a data terminal and a source terminal. The word line is coupled to the control terminal of the first memory cell and the control terminal of the second memory cell. The bit line is coupled to the data terminal of the first memory cell and the data terminal of the second memory cell. The first source line is coupled to the source terminal of the first memory cell for receiving a first source voltage. The second source line is coupled to the source terminal of the second memory cell for receiving a second source voltage.

### BACKGROUND OF THE INVENTION

### 1. Field of the Invention

The present invention relates to electronic circuits, in particular to a memory device.

### 2. Description of the Prior Art

Magnetoresistive random access memory (MRAM) is a non-volatile memory with advantages such as high read and write speed, high density, high durability, low power consumption and radiation resistance. MRAM changes the magnetization direction and resistance by controlling the signals on the word line, bit line and source line, and then writes data into the memory cell. However, since each memory cell in each column of memory cells needs to be controlled individually during read and write operations, many bit lines need to be provided in the MRAM to control the memory cells in the MRAM, so the circuit area cannot be reduced.

### SUMMARY OF THE INVENTION

According to an embodiment of the invention, a memory device includes a first memory cell, a second memory cell, a word line, a bit line, a first source line and a second source line. The first memory cell includes a control terminal, a data terminal and a source terminal. The second memory cell includes a control terminal, a data terminal and a source terminal. The word line is coupled to the control terminal of the first memory cell and the control terminal of the second memory cell. The bit line is coupled to the data terminal of the first memory cell and the data terminal of the second memory cell. The first source line is coupled to the source terminal of the first memory cell and is used to receive the first source voltage. The second source line is coupled to the source terminal of the second memory cell and is used to receive a second source voltage, wherein the second source voltage is different from the first source voltage.

According to another embodiment of the invention, a memory device includes a first source line, a second source line, a first bit line, a second bit line, a first memory cell, a second memory cell, a first bit line connection layer and a second bit line connection layer. The first source line and the second source line are formed along the first direction, and the second source line and the first source line are separated from each other. The first bit line and the second bit line are formed along the first direction. The first memory cell includes a first diffusion layer and a third diffusion layer. The first diffusion layer at least partially overlaps with the first bit line, and the third diffusion layer at least partially overlaps with the first bit line. The second memory cell includes a second diffusion layer and a fourth diffusion layer. The second diffusion layer at least partially overlaps with the second bit line, and the fourth diffusion layer at least partially overlaps with the second bit line. The first bit line connection layer is formed along the second direction and at least partially overlaps with the first diffusion layer and the second diffusion layer. The second bit line connection layer is formed along the second direction and at least partially overlaps with the third diffusion layer and the fourth diffusion layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic circuit diagram of a memory device according to an embodiment of the invention.

FIG. 2A is a schematic circuit diagram of another memory cell according to an embodiment of the invention.

FIG. 2B is a schematic circuit diagram of another memory device according to an embodiment of the invention.

FIG. 3A is a schematic circuit diagram of another memory cell according to an embodiment of the invention.

FIG. 3B is a schematic circuit diagram of another memory device according to an embodiment of the invention.

FIG. 4 is a schematic layout diagram of the memory device in FIG. 1.

FIG. 5 is another schematic layout diagram of the memory device in FIG. 1.

FIG. 6 is a cross-sectional view of the memory device in FIG. 4 along the line 6-6′.

### DETAILED DESCRIPTION

As used herein, the control terminal of a transistor may be the gate terminal, the first terminal of a transistor may be one of the drain terminal and the source terminal, and the second terminal of a transistor may be the other one of the drain terminal and the source terminal. For example, the first terminal of the transistor can be the drain terminal and the second terminal of the transistor can be the source terminal. For example, the first terminal of the transistor can be the source terminal, and the second terminal of the transistor can be the drain terminal. In the drawings of this specification, the drain terminal, source terminal and gate terminal of a transistor can be marked with D, S and G respectively. The drain terminal (D), source terminal(S) and gate terminal (G) of the transistor are only for explanation and is not intended to limit the invention. Reasonable design changes can be made according to the characteristics of the transistor without deviating from the scope of the invention. The memory element described herein may be a magnetoresistive random access memory (MRAM) using a magnetic tunnel junction (MTJ) as the memory cell. The magnetic tunnel junction comprises two magnetic material layers and an insulating layer between the two magnetic material layers. When the magnetization directions of the two magnetic material layers are the same, the magnetic tunnel junction has a low resistance, representing data “1”; when the magnetization directions of the two magnetic material layers are opposite, the magnetic tunnel junction has a high resistance, representing data “0”. The magnetic tunnel junction can be set to a predetermined resistance state to store data.

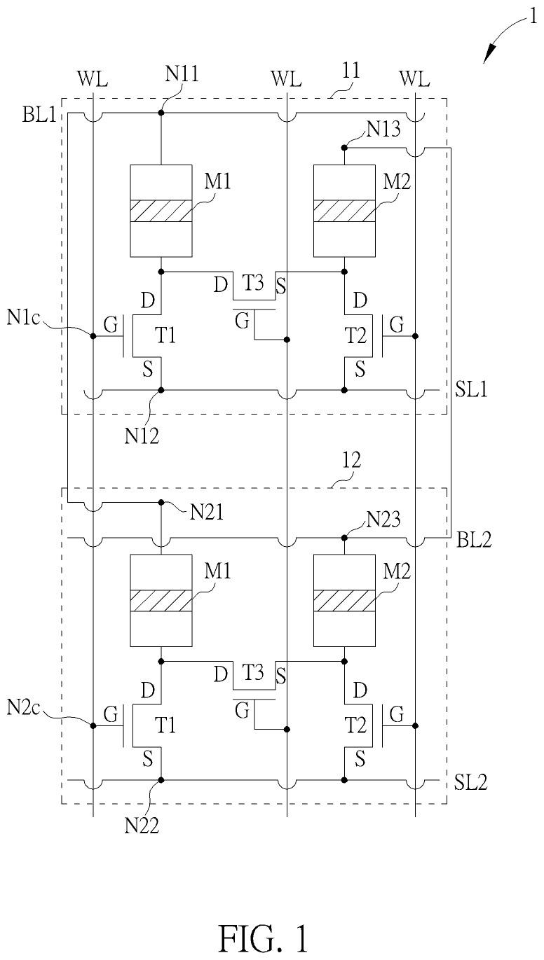

FIG. 1 is a schematic circuit diagram of a memory device 1 according to an embodiment of the invention. The memory device 1 may include an array of memory cells. At least two memory cells share the same bit line and use at least two separate source lines to complete the read and write operations of the at least two memory cells, thereby saving the number of bit lines, simplifying the circuit layout and reducing the circuit area.

The memory device 1 may include a first memory cell 11, a second memory cell 12, a word line WL, a first bit line BL1, a first source line SL1 and a second source line SL2. The first memory cell 11 and the second memory cell 12 may be adjacent to each other. The first memory cell 11 may include a control terminal N1c, a first data terminal N11 and a source terminal N12. The second memory cell 12 may include a control terminal N2c, a first data terminal N21 and a source terminal N22. The word line WL may be coupled to the control terminal N1c of the first memory cell 11 and the control terminal N2c of the second memory cell 12. The first bit line BL1 is coupled to the first data terminal N11 of the first memory cell 11 and the first data terminal N21 of the second memory cell 12. The first source line SL1 is coupled to the source terminal N12 of the first memory cell 11 to receive a first source voltage. The second source line SL2 is coupled to the source terminal N22 of the second memory cell 12 to receive a second source voltage. The first memory cell 11 and the second memory cell 12 may share the first bit line BL1 and use first source lines SL1 and second source lines SL2 respectively. The first bit line BL1, the first source line SL1 and the second source line SL2 may be further coupled to a controller. The controller may control the first memory cell 11 and the second memory cell 12 to perform read and write operations via the first bit line BL1 by providing the first source voltage to the first source line SL1 and providing the second source voltage to the second source line SL2. Since the first memory cell 11 and the second memory cell 12 share the first bit line BL1, only one of the first memory cell 11 and the second memory cell 12 can be enabled at a time to perform read and write operations, and the other one can be disabled to prevent from performing read or write operations.

The controller can respectively control the first memory cell 11 and the second memory cell 12 via the first source voltage and the second source voltage. The second source voltage may be different from the first source voltage. The first source voltage may be one of an enabling voltage and a disabling voltage, and the second source voltage may be the remaining one of the enabling voltage and the disabling voltage. In some embodiments, the enabling voltage may be 0V, and the disabling voltage may be a floating voltage. For example, if the first source voltage is the enabling voltage and the second source voltage is the disabling voltage, the first memory cell 11 can be enabled to perform read and write operations via the first bit line BL1, and the second memory cell 12 can be disabled to cease from performing read and write operations. In another example, if the first source voltage is the disabling voltage and the second source voltage is the enabling voltage, the first memory cell 11 may be disabled to cease from performing read and write operations, and the second memory cell 12 can be enabled to perform read and write operations via the first bit line BL1.

The first memory cell 11 and the second memory cell 12 may each have 3 transistors and 2 memory elements (referred to as 3T2M architecture). For the 3T2M architecture, the first memory cell 11 may further comprise a second data terminal N13, and the second memory cell 12 may further comprise a second data terminal N23. The memory device 1 may further comprise a second bit line BL2 coupled to the second data terminal N13 of the first memory cell 11 and the second data terminal N23 of the second memory cell 12. Therefore, the first memory cell 11 and the second memory cell 12 further share the second bit line BL2, and the second bit line BL2 may be further coupled to the controller.

The first memory cell 11 may include a first memory element M1, a second memory element M2, a first transistor T1, a second transistor T2, and a third transistor T3. The first memory element M1 comprises a first terminal coupled to the first data terminal N11 of the first memory cell 11, and a second terminal. The second memory element M2 comprises a first terminal coupled to the second data terminal N13 of the first memory cell 11, and a second terminal. The first transistor T1 comprises a control terminal G coupled to the control terminal N1c of the first memory cell 11, a first terminal D coupled to the second terminal of the first memory element M1 of the first memory cell 11, and a second terminal S coupled to the source terminal N12 of the first memory cell 11. The second transistor T2 comprises a control terminal G coupled to the control terminal N1c of the first memory cell 11, a first terminal D coupled to the second terminal of the second memory element M2 of the first memory cell 11, and a second terminal S coupled to the source terminal N12 of the first memory cell 11. The third transistor T3 comprises a control terminal G coupled to the control terminal N1c of the first memory cell 11, a first terminal D coupled to the first terminal D of the first transistor T1 of the first memory cell 11; and the second terminal S coupled to the first terminal D of the second transistor T2 of the first memory cell 11.

The second memory cell 12 may include a first memory element M1, a second memory element M2, a first transistor T1, a second transistor T2, and a third transistor T3. The first memory element M1 comprises a first terminal coupled to the first data terminal N21 of the second memory cell 12, and a second terminal. The second memory element M2 comprises a first terminal coupled to the second data terminal N23 of the second memory cell 12, and a second terminal. The first transistor T1 includes a control terminal G coupled to the control terminal N2c of the second memory cell 12, a first terminal D coupled to the second terminal of the first memory element M1 of the second memory cell 12, and a second terminal S coupled to the source terminal N22 of the second memory cell 12. The second transistor T2 comprises a control terminal G coupled to the control terminal N2c of the second memory cell 12, a first terminal D coupled to the second terminal of the second memory element M2 of the second memory cell 12, and a second terminal S coupled to the source terminal N22 of the second memory cell 12. The third transistor T3 comprises a control terminal G coupled to the control terminal N2c of the second memory cell 12, a first terminal D coupled to the first terminal D of the first transistor T1 of the second memory cell 12, and a second terminal S coupled to the first terminal D of the second transistor T2 of the second memory cell 12.

The first memory element M1 and the second memory element M2 of the first memory cell 11 and the first memory element M1 and the second memory element M2 of the second memory cell 12 are magnetic tunnel junctions, and the first transistor M1, the second transistor M2 and the third transistor M3 of the first memory cell 11 and the first transistor M1, the second transistor M2 and the third transistor M3 of the second memory cell 12 can be the same kind of transistor. In this embodiment, the first transistor M1, the second transistor M2 and the third transistor M3 of the first memory cell 11 and the first transistor M1, the second transistor M2 and the third transistor M3 of the second memory cell 12 may be, but are not limited to, N-type metal-oxide-semiconductor field-effect transistors (MOSFET). In some embodiments, the first transistor M1, the second transistor M2 and the third transistor M3 of the first memory cell 11 and the first transistor M1, the second transistor M2 and the third transistor M3 of the second memory cell 12 may also be P-type MOSFETS or other types of transistors.

The controller will only perform read/write operations on one memory element in the first memory cell 11 or the second memory cell 12 via one of the first bit line BL1 and the second bit line BL2 at a time. For example, to write to the first memory element M1 of the first memory cell 11, the controller may set the first source voltage on the first source line SL1 to the enabling voltage, set the second source voltage on the second source line SL2 to the disabling voltage, set the control voltage on the word line WL to the turn-on voltage (for example, 1.8V), load the data to the first bit line BL1, and float the second bit line BL2, thereby setting the first memory element M1 of the first memory cell 11 to a corresponding resistance according to the data. Since the control voltage on the word line WL is the turn-on voltage and the first source voltage on the first source line SL1 is the enabling voltage, the first transistor T1, the second transistor T2 and the third transistor T3 of the first memory cell 11 are all turned on. The first memory cell 11 can write data into the first memory element M1 of the first memory cell 11 according to the total current of the two paths (the first transistor T1, and the stacked third transistor T3 and the second transistor T2), thereby increasing the writing current and accelerating the writing operation. Since the second source voltage on the second source line SL2 is the disabling voltage, even if the control voltage on the word line WL is the turn-on voltage, the first transistor T1, the second transistor and the third transistor T3 of the second memory cell 12 are still turned off, thereby disabling the second memory cell 12.

In another example, to read the second memory element M2 of the second memory cell 12, the controller may set the first source voltage on the first source line SL1 to the disabling voltage, set the second source voltage on the second source line SL2 to the enabling voltage, and set the control voltage on the word line WL to the turn-on voltage, float the first bit line BL1, and read the data stored in the second memory element M2 of the second memory cell 12 via the second bit line BL2. Since the control voltage on the word line WL is the turn-on voltage and the second source voltage on the second source line SL2 is the enabling voltage, the first transistor T1, the second transistor T2 and the third transistor T3 of the second memory cell 12 are all turned on. The second memory cell 12 can read the second memory element M2 of the second memory cell 12 according to the total current of the two paths (the second transistor T2, and the stacked third transistor T3 and the first transistor T1), thereby increasing the read current and accelerating the read operation. Since the first source voltage on the first source line SL1 is the disabling voltage, even if the control voltage on the word line WL is the turn-on voltage, the first transistor T1, the second transistor T2 and the third transistor T3 of the first memory cell 11 are still turned off, thereby disabling the first memory cell 11.

For the 3T2M architecture, in the related art, 4 bit lines and 1 source line are used to read and write 4 memory elements. In contrast, the present embodiment shares the first bit line BL1 and the second bit line BL2 and uses separate first source line SL1 and second source line SL2 to read and write 4 memory elements. Therefore, the related art uses 5 lines (4+1) to control the reading and writing of 4 memory elements, while the present embodiment uses 4 lines (2+2) to control the reading and writing of 4 memory elements. Therefore, compared to related art, the present embodiment uses fewer lines to achieve read and write operations of 4 memory elements, thereby reducing the number of bit lines, simplifying circuit layout and reducing circuit area. If the remaining memory cells in the memory device 1 are also configured and operated in a manner similar to the first memory cell 11 and the second memory cell 12, then the total number of lines in the related art (=N bit lines+1 source lines) will significantly exceed the total number of lines in this embodiment (=N/2 bit lines+2 source lines). Therefore, compared to related art, the present embodiment can reduce the total number of bit lines of the memory device 1, simplify the circuit layout, and reduce the circuit area.

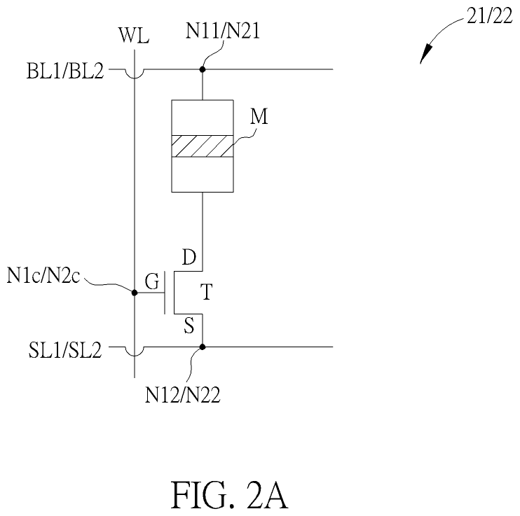

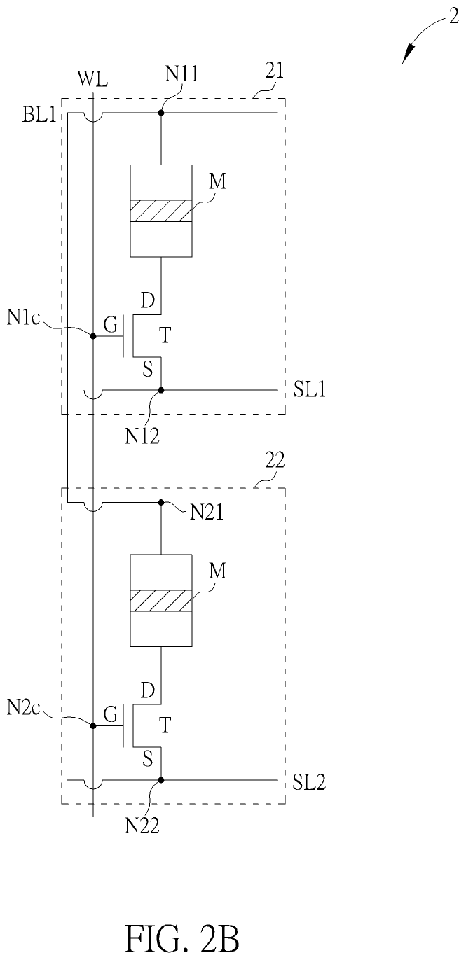

FIG. 2A is a schematic circuit diagram of another memory cell 21/22 according to an embodiment of the invention. The memory cell 21/22 can replace the first memory cell 11 and the second memory cell 12 in the memory device 1 to form a memory device 2, as shown in FIG. 2B and will be explained in detail in subsequent paragraphs.

The memory cell 21/22 may include 1 memory element M and 1 transistor T (referred to as 1T1M architecture). The memory element M includes a first terminal coupled to the bit line BL1 via the first data terminals N11/N21 of the memory cells 21/22, and a second terminal. The transistor T includes a control terminal G coupled to the word line WL via the control terminals N1c/N2c of the memory cell 21/22, a first terminal D coupled to the second terminal of the memory element M, and a second terminal S coupled to the source lines SL1/SL2 via the source terminals N12/N22 of the memory cells 21/22.

To read/write the memory element M, the source voltage on the source lines SL1/SL2 can be set to the enabling voltage and the control voltage on the word line WL can be set to the turn-on voltage, thereby reading the data of the memory element M via the bit line BL1 or setting the memory element M of the memory cell 21/22 to the corresponding resistor according to the data on the bit line BL1. Since the control voltage on the word line WL is the turn-on voltage and the source voltage on the source lines SL1/SL2 is the enabling voltage, the transistor T is turned on, and the memory cell 21/22 can read data from the memory element M or write data into the memory element M according to the current flowing through the first terminal D and the second terminal S of the transistor T. Compared to the first memory cell 11/the second memory cell 12, the controller only reads/writes the memory cell 21/22 via one conduction path (the first terminal D and the second terminal S of the transistor T), so the read/write current is smaller and the read/write operation is slower.

Referring to FIG. 2B, the difference between the memory device 2 and the memory device 1 lies in the memory cells and bit lines. Other components of the memory device 2 are similar to the memory device 1, and will not be repeated here. The following explains the differences between the memory device 2 and the memory device 1. The first memory cell 21 and the second memory cell 22 in the memory device 2 may be adjacent to each other, may only share the bit line BL1 and use separate first source lines SL1 and second source lines SL2 respectively.

The first memory cell 21 comprises a memory element M and a transistor T. The memory element M includes a first terminal coupled to the first data terminal N11 of the first memory cell 21, and a second terminal. The transistor T comprises a control terminal G coupled to the control terminal N1c of the first memory cell 21, a first terminal D coupled to the second terminal of the memory element M of the first memory cell 21, and a second terminal S coupled to the source terminal N12 of the first memory cell 21. The second memory cell 22 comprises a memory element M and a transistor T. The memory element M comprises a first terminal coupled to the first data terminal N21 of the second memory cell 22, and a second terminal. The transistor T comprises a control terminal G coupled to the control terminal N2c of the second memory cell 22, a first terminal D coupled to the second terminal of the memory element M of the second memory cell 22, and a second terminal S coupled to the source terminal N22 of the second memory cell 22.

The memory element M of the first memory cell 21 and the memory element M of the second memory cell 22 are magnetic tunnel junctions, and the transistor T of the first memory cell 21 and the transistor T of the second memory cell 22 may be the same type of transistor. In this embodiment, the transistor T of the first memory cell 21 and the transistor T of the second memory cell 22 may be, but are not limited to, N-type MOSFETs. In some embodiments, the transistor T of the first memory cell 21 and the transistor T of the second memory cell 22 may also be P-type MOSFETs or other types of transistors.

The controller can enable one of the first memory cell 21 and the second memory cell 22 to perform read and write operations at a time, and disable the other to prohibit read and write operations. For example, to write to the memory element M of the first memory cell 21, the controller can set the first source voltage on the first source line SL1 to the enabling voltage, set the second source voltage on the second source line SL2 to the disabling voltage, set the control voltage on the word line WL to the turn-on voltage (for example, 1.8V), load the data into the first bit line BL1, thereby setting the memory element M of the first memory cell 21 to a corresponding resistor according to the data. Since the control voltage on the word line WL is the turn-on voltage and the first source voltage on the first source line SL1 is the enabling voltage, the transistor T of the first memory cell 21 is turned on. The first memory cell 21 can write data into the memory element M of the first memory cell 21 according to the current flowing through the first terminal D and the second terminal S of the transistor T. Since the second source voltage on the second source line SL2 is the disabling voltage, even if the control voltage on the word line WL is the turn-on voltage, the transistor T of the second memory cell 22 will still be turned off, thereby disabling the second memory cell 22.

In another example, to read the second memory element M of the second memory cell 22, the controller may set the first source voltage on the first source line SL1 to the disabling voltage, set the second source voltage on the second source line SL2 to the enabling voltage, and set the control voltage on the word line WL to the turn-on voltage, and read the data stored in the memory element M of the second memory cell 22 via the bit line BL1. Since the control voltage on the word line WL is the turn-on voltage and the second source voltage on the second source line SL2 is the enabling voltage, the transistor T of the second memory cell 22 is turned on, and the second memory cell 22 can read the memory element M of the second memory cell 22 according to the current flowing through the first terminal D and the second terminal S of the transistor T. Since the first source voltage on the first source line SL1 is the disabling voltage, even if the control voltage on the word line WL is the turn-on voltage, the transistor T of the first memory cell 21 will still be turned off, thereby disabling the first memory cell 21.

For the 1T1M architecture, in the related art, 2 bit lines and 1 source line are used to read and write 2 memory elements. And the present embodiment shares the bit line BL1 and uses separate first source line SL1 and second source line SL2 to read and write 2 memory elements. Therefore, the related art uses 3 lines (2+1) to control the reading and writing of 2 memory elements, the present embodiment also uses 3 lines (1+2) to control the reading and writing of 2 memory elements. If the remaining memory cells in the memory device 2 are also configured and operated in a manner similar to the first memory cell 21 and the second memory cell 22, then the total number of lines in the related art (=N bit lines+1 source lines) will significantly exceed the total number of lines in this embodiment (=N/2 bit lines+2 source lines). Therefore, compared to related art, the present embodiment can reduce the total number of bit lines of the memory device 2, simplify the circuit layout, and reduce the circuit area.

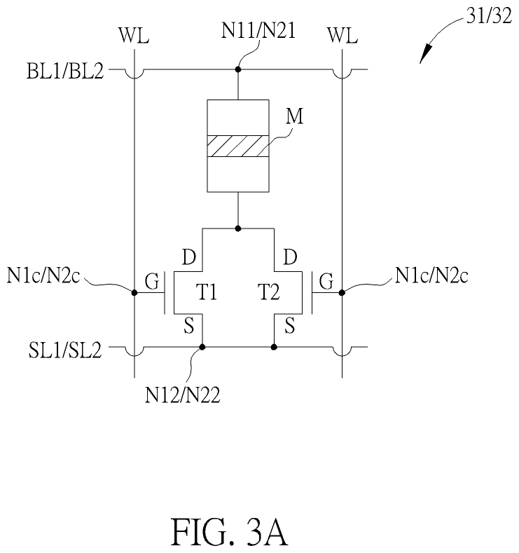

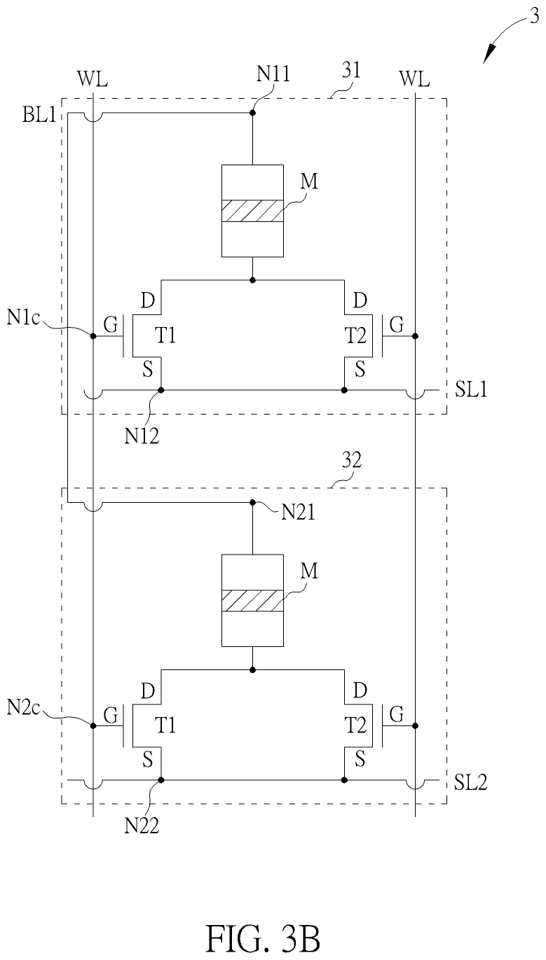

FIG. 3A is a schematic circuit diagram of another memory cell 31/32 according to an embodiment of the invention. The memory cell 31/32 can replace the first memory cell 21 and the second memory cell 22 in the memory device 2 to form the memory device 3, as shown in FIG. 3B and will be described in detail in subsequent paragraphs.

The memory cell 31/32 may include 1 memory element M, a first transistor T1 and a second transistor T2 (referred to as 2T1M architecture). The memory element M comprises a first terminal coupled to the bit line BL1 via the first data terminals N11/N21 of the memory cells 31/32, and a second terminal. The first transistor T1 comprises a control terminal G coupled to the word line WL via the control terminals N1c/N2c of the memory cell 31/32, a first terminal D coupled to the second terminal of the memory element M of the memory cell 31/32, and a second terminal S coupled to the source line SL1/SL2 via the source terminals N12/N22 of the memory cells 31/32. The second transistor T2 comprises a control terminal G coupled to the word line WL via the control terminals N1c/N2c of the memory cell 31/32, a first terminal D coupled to the second terminal of the memory element M of the memory cell 31/32, and a second terminal S coupled to the source line SL1/SL2 via the source terminals N12/N22 of the memory cells 31/32.

To read/write the memory element M, the source voltage on the source lines SL1/SL2 can be set to the enabling voltage and the control voltage on the word line WL can be set to the turn-on voltage, thereby reading the data of the memory element M via the bit line BL1 or setting the memory element M of the memory cell 31/32 to a corresponding resistor according to the data on the bit line BL1. Since the control voltage on the word line WL is the turn-on voltage and the source voltage on the source lines SL1/SL2 is the enabling voltage, the first transistor T1 and the second transistor T2 are both turned on. The first memory cell 11 can read data from the memory element M or write data into the memory element M according to the total current flowing through the first transistor T1 and the second transistor T2, thereby increasing the read/write current, and accelerating read/write operations. Compared to the first memory cell 11/second memory cell 12, the memory cell 31/32 also reads/writes memory cell 31/32 via two conduction paths (the first transistor T1 and the second transistor T2), so the read/write current is the same and the read/write operation speed is the same. Compared to the first memory cell 21/the second memory cell 22, the memory cell 31/32 reads/writes the memory cell 31/32 via two conduction paths (the first transistor T1 and the second transistor T2), so the read/write current is larger and the read/write operation is faster

Referring to FIG. 3B, the difference between the memory device 3 and the memory device 2 lies in the memory cells. Other components of the memory device 3 are similar to the memory device 2, and will not be repeated here. The following explains the differences between the memory device 3 and the memory device 2. The first memory cell 31 and the second memory cell 32 in the memory device 3 may be adjacent to each other, may only share the bit line BL1 and use separate first source lines SL1 and second source lines SL2 respectively.

The first memory cell 31 comprises a memory element M, a first transistor T1 and a second transistor T2. The memory element M comprises a first terminal coupled to the first data terminal N11 of the first memory cell 31, and a second terminal. The first transistor T1 comprises a control terminal G coupled to the control terminal N1c of the first memory cell 31, a first terminal D coupled to the second terminal of the memory element M of the first memory cell 31, and a second terminal S coupled to the source terminal N12 of the first memory cell 31. The second transistor T2 comprises a control terminal G coupled to the control terminal N1c of the first memory cell 31, a first terminal D coupled to the second terminal of the memory element M of the first memory cell 31, and a second terminal S coupled to the source terminal N12 of the first memory cell 31. The second memory cell 32 comprises a memory element M, a first transistor T1 and a second transistor T2. The memory element M comprises a first terminal coupled to the first data terminal N21 of the second memory cell 32, and a second terminal. The first transistor T1 comprises a control terminal G coupled to the control terminal N2c of the second memory cell 32, a first terminal D coupled to the second terminal of the memory element M of the second memory cell 32, and a second terminal S coupled to the source terminal N22 of the second memory cell 32. The second transistor T2 comprises a control terminal G coupled to the control terminal N2c of the second memory cell 32, a first terminal D coupled to the second terminal of the memory element M of the second memory cell 32, and a second terminal S coupled to the source terminal N22 of the second memory cell 32.

The memory element M of the first memory cell 31 and the memory element M of the second memory cell 32 are magnetic tunnel junctions, and the first transistor T1 and the second transistor T2 of the first memory cell 31 and the first transistor T1 and the second transistor T2 of the second memory cell 32 may be the same type of transistor. In this embodiment, the first transistor T1 and the second transistor T2 of the first memory cell 31 and the first transistor T1 and the second transistor T2 of the second memory cell 32 may be, but are not limited to N-type MOSFETs. In some embodiments, the first transistor T1 and the second transistor T2 of the first memory cell 31 and the first transistor T1 and the second transistor T2 of the second memory cell 32 may also be P-type MOSFETs or other types of transistors.

The controller can enable one of the first memory cell 31 and the second memory cell 32 to perform read and write operations at a time, and disable the other to prohibit read and write operations. The first memory cell 31 and the second memory cell 32 may be controlled in a manner similar to the first memory cell 21 and the second memory cell 22, and will not be repeated here.

For the 2T1M architecture, in the related art, 2 bit lines and 1 source line are used to read and write 2 memory elements. And the present embodiment shares the bit line BL1 and uses separate first source line SL1 and second source line SL2 to read and write 2 memory elements. Therefore, the related art uses 3 lines (2+1) to control the reading and writing of 2 memory elements, the present embodiment also uses 3 lines (1+2) to control the reading and writing of 2 memory elements. If the remaining memory cells in the memory device 3 are also configured and operated in a manner similar to the first memory cell 31 and the second memory cell 32, then the total number of lines in the related art (=N bit lines+1 source lines) will significantly exceed the total number of lines in this embodiment (=N/2 bit lines+2 source lines). Therefore, compared to related art, the present embodiment can reduce the total number of bit lines of the memory device 3, simplify the circuit layout, and reduce the circuit area.

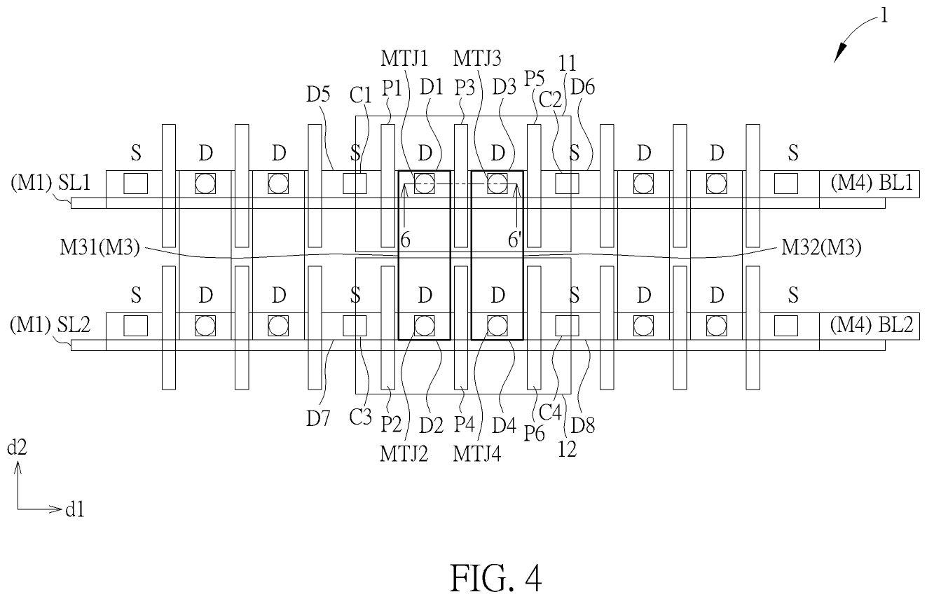

FIG. 4 is a schematic layout diagram of the memory device 1 in FIG. 1. The memory device 1 comprises a first source line SL1, a second source line SL2, a first bit line BL1, a second bit line BL2, a first bit line connection layer M31, a second bit line connection layer M32, the first to sixth polysilicon layers P1 to P6, the first to eighth diffusion layers D1 to D8, and the first to fourth magnetic tunnel junctions MTJ1 to MTJ4. The first diffusion layer D1, the third diffusion layer D3, the fifth diffusion layer D5, the sixth diffusion layer D6, the first polysilicon layer P1, the third polysilicon layer P3, the fifth polysilicon layer P5, the first magnetic tunnel junction MTJ1 and the third magnetic tunnel junction MTJ3 may form the first memory cell 11. The second diffusion layer D2, the fourth diffusion layer D4, the seventh diffusion layer D7, the eighth diffusion layer D8, the second polysilicon layer P2, the fourth polysilicon layer P4, the sixth polysilicon layer P6, the second magnetic tunnel junction MTJ2 and the fourth magnetic tunnel junction MTJ4 may form the second memory cell 12.

The first source line SL1 and the second source line SL2 may be formed along the first direction d1. The second source line SL2 and the first source line SL1 may be separated from each other. The first source line SL1 and the second source line SL2 are formed by the same conductive layer M1. The first bit line BL1 and the second bit line BL2 may be formed along the first direction d1. The first bit line BL1 and the second bit line BL2 may separate from each other. The first bit line BL1 and the second bit line BL2 are formed by the same conductive layer M4.

The first polysilicon layer P1 may be formed along the second direction d2, and may at least partially overlap with the first source line SL1 and the first bit line BL1. The first direction d1 may be perpendicular to the second direction d2. The first polysilicon layer P1 can form the control terminal G of the first transistor T1 of the first memory cell 11 in FIG. 1. The second polysilicon layer P2 may be formed along the second direction d2, and may at least partially overlap with the second source line SL2 and the second bit line BL2. The second polysilicon layer P2 can form the control terminal G of the first transistor T1 of the second memory cell 12 in FIG. 1. The third polysilicon layer P3 may be formed along the second direction d2, and may at least partially overlap with the first source line SL1 and the first bit line BL1. The third polysilicon layer P3 can form the control terminal G of the third transistor T3 of the first memory cell 11 in FIG. 1. The fourth polysilicon layer P4 may be formed along the second direction d2 and may at least partially overlap with the second source line SL2 and the second bit line BL2. The fourth polysilicon layer P4 can form the control terminal G of the third transistor T3 of the second memory cell 12 in FIG. 1. The fifth polysilicon layer P5 may be formed along the second direction d2, and may at least partially overlap with the first source line SL1 and the first bit line BL1. The fifth polysilicon layer P5 can form the control terminal G of the second transistor T2 of the first memory cell 11 in FIG. 1. The sixth polysilicon layer P6 may be formed along the second direction d2 and may at least partially overlap with the second source line SL2 and the second bit line BL2. The sixth polysilicon layer P6 can form the control terminal G of the second transistor T2 of the second memory cell 12 in FIG. 1. The first polysilicon layer P1, the second polysilicon layer P2, the third polysilicon layer P3, the fourth polysilicon layer P4, the fifth polysilicon layer P5 and the sixth polysilicon layer P6 are formed by the same polysilicon layer. The first polysilicon layer P1, the second polysilicon layer P2, the third polysilicon layer P3, the fourth polysilicon layer P4, the fifth polysilicon layer P5 and the sixth polysilicon layer P6 can be separated from each other. In some embodiments, the first polysilicon layer P1 and the second polysilicon layer P2 can also be coupled to each other; the third polysilicon layer P3 and the fourth polysilicon layer P4 can also be coupled to each other; and the fifth polysilicon layer P5 and the sixth polysilicon layer P6 may also be coupled to each other.

The first diffusion layer D1 may at least partially overlap with the first bit line BL1 and may be located between the first polysilicon layer P1 and the third polysilicon layer P3. The first diffusion layer D1 can form the first terminal D of the first transistor T1 of the first memory cell 11 and the first terminal D of the third transistor T3 of the first memory cell 11 in FIG. 1. The second diffusion layer D2 may at least partially overlap with the second bit line BL2 and may be located between the second polysilicon layer P2 and the fourth polysilicon layer P4. The second diffusion layer D2 can form the first terminal D of the first transistor T1 of the second memory cell 12 and the first terminal D of the third transistor T3 of the first memory cell 11 in FIG. 1. The third diffusion layer D3 may at least partially overlap with the first bit line BL1 and may be located between the third polysilicon layer P3 and the fifth polysilicon layer P5. The third diffusion layer D3 can form the first terminal D of the second transistor T2 of the first memory cell 11 and the second terminal S of the third transistor T3 of the first memory cell 11 in FIG. 1. The fourth diffusion layer D4 may at least partially overlap with the second bit line BL2 and may be located between the fourth polysilicon layer P4 and the sixth polysilicon layer P6. The fourth diffusion layer D4 can form the first terminal D of the second transistor T2 of the second memory cell 12 and the second terminal S of the third transistor T3 of the first memory cell 11 in FIG. 1.

The fifth diffusion layer D5 may at least partially overlap with the first source line SL1, and may form the second terminal S of the first transistor T1 of the first memory cell 11 in FIG. 1. The sixth diffusion layer D6 may at least partially overlap with the first source line SL1 and may form the second terminal S of the second transistor T2 of the first memory cell 11 in FIG. 1. The seventh diffusion layer D7 may at least partially overlap with the second source line SL2 and may form the second terminal S of the first transistor T1 of the second memory cell 12 in FIG. 1. The eighth diffusion layer D8 may at least partially overlap with the second source line SL2 and may form the second terminal S of the second transistor T2 of the second memory cell 12 in FIG. 1. The first diffusion layer D1, the second diffusion layer D2, the third diffusion layer D3, the fourth diffusion layer D4, the fifth diffusion layer D5, the sixth diffusion layer D6, the seventh diffusion layer D7 and the eighth diffusion layer D8 are formed by same diffusion layer.

The first magnetic tunnel junction MTJ1 may overlap with the first diffusion layer D1 and the first bit line BL1, and may form the first memory element M1 of the first memory cell 11 in FIG. 1. The second magnetic tunnel junction MTJ2 may overlap with the second diffusion layer D2 and the second bit line BL2, and may form the first memory element M1 of the second memory cell 12 in FIG. 1. The third magnetic tunnel junction MTJ3 may overlap with the third diffusion layer D3 and the first bit line BL1, and may form the second memory element M2 of the first memory cell 11 in FIG. 1. The fourth magnetic tunnel junction MTJ4 may overlap with the fourth diffusion layer D4 and the second bit line BL2, and may form the second memory element M2 of the second memory cell 12 in FIG. 1.

The first bit line connection layer M31 can be formed along the second direction d2, at least partially overlapping with the first diffusion layer D1 and the second diffusion layer D2, configured to couple the first terminal D of the first transistor T1 of the first memory cell 11 and the first terminal D of the first transistor T1 of the second memory cell 12 in FIG. 1. The second bit line connection layer M32 may be formed along the second direction d2, at least partially overlapping with the third diffusion layer D3 and the fourth diffusion layer D4, configured to couple the first terminal D of the second transistor T2 of the first memory cell 11 and the first terminal D of the second transistor T2 of the second memory cell 12 in FIG. 1. The first bit line connection layer M31 and the second bit line connection layer M32 are formed by the same conductive layer M3.

The memory device 1 may further comprise the first to fourth contacts C1 to C4. The first contact C1 may overlap with the fifth diffusion layer D5. The second contact C2 may overlap with the sixth diffusion layer D6. The third contact C3 may overlap with the seventh diffusion layer D7. The fourth contact C4 may overlap with the eighth diffusion layer D8.

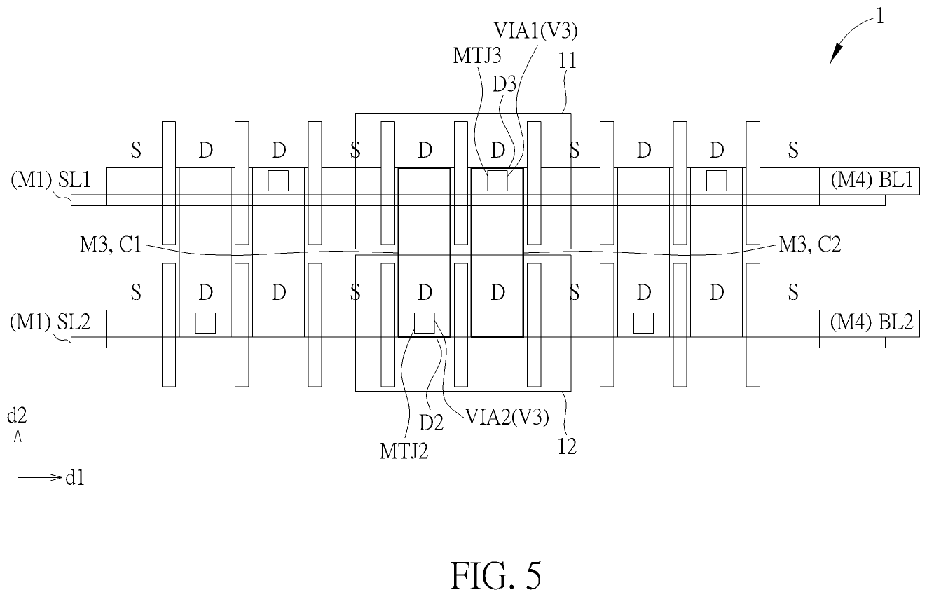

FIG. 5 is another schematic layout diagram of the memory device 1. The memory device 1 may further include a first via VIA1 and a second via VIA2. The first via VIA1 may overlap with the third diffusion layer D3 and the third magnetic tunnel junction MTJ3 to couple the third diffusion layer D3 and the third magnetic tunnel junction MTJ3. The via VIA2 may overlap with the second diffusion layer D2 and the second magnetic tunnel junction MTJ2 to couple the second diffusion layer D2 and the second magnetic tunnel junction MTJ2. The first via VIA1 and the second via VIA2 are formed by the same via layer V3.

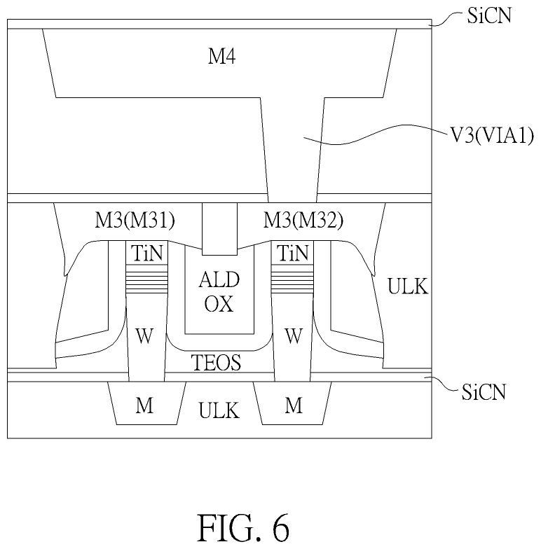

FIG. 6 is a sectional view of the memory device 1 in FIG. 4 along the cut line 6-6′, comprising silicon carbon nitride (SiCN) layer, conductive layer M4, via layer V3, conductive layer M3, ultra low-k layer ULK, titanium nitride (TiN) layer, ALD OX layer, tungsten (W) layer, tetraethyl orthosilicate (TEOS) layer, and conductive layer M. FIG. 6 shows the conductive layer M4 coupled to the second bit line connection layer M32 of the conductive layer M3 via the first via VIA1 of the via layer V3, and the second bit line connection layer M32 of the conductive layer M3 and the first bit line connection layer M31 of the conductive layer M3 are separated. The first bit line connection layer M31 and the second bit line connection layer M32 are disposed on their respective magnetic tunnel junctions.

In the memory device in the embodiment of the present invention, at least two memory cells share the same bit line and use at least two separate source lines to complete the read and write operations of at least two memory cells, saving the number of bit lines, simplifying the circuit layout and reducing the circuit area.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A memory device comprising:
a first memory cell comprising a control terminal, a first data terminal and a source terminal;
a second memory cell comprising a control terminal, a first data terminal and a source terminal;
a word line coupled to the control terminal of the first memory cell and the control terminal of the second memory cell;
a bit line coupled to the first data terminal of the first memory cell and the first data terminal of the second memory cell;
a first source line coupled to the source terminal of the first memory cell and configured to receive a first source voltage;
a second source line coupled to the source terminal of the second memory cell and configured to receive a second source voltage, the second source voltage being different from the first source voltage.

2. The memory device of claim 1, wherein the first source voltage is one of an enabling voltage and a disabling voltage, and the second source voltage is a remaining one of the enabling voltage and the disabling voltage.

3. The memory device of claim 1, wherein:
the first memory cell comprises:
a memory element comprising a first terminal coupled to the first data terminal of the first memory cell, and a second terminal; and
a transistor comprising a control terminal coupled to the control terminal of the first memory cell, a first terminal coupled to the second terminal of the memory element of the first memory cell, and a second terminal coupled to the source terminal of the first memory cell; and
the second memory cell comprises:
a memory element comprising a first terminal coupled to the first data terminal of the second memory cell, and a second terminal; and
a transistor comprising a control terminal coupled to the control terminal of the second memory cell, a first terminal coupled to the second terminal of the memory element of the second memory cell, and a second terminal coupled to the source terminal of the second memory cell.

4. The memory device of claim 3, wherein the memory element of the first memory cell and the memory element of the second memory cell are magnetic tunnel junctions, and the transistor of the first memory cell and the transistor of the second memory cell are N-type transistors.

5. The memory device of claim 1, wherein:
the first memory cell comprises:
a memory element comprising a first terminal coupled to the first data terminal of the first memory cell, and a second terminal;
a first transistor comprising a control terminal coupled to the control terminal of the first memory cell, a first terminal coupled to the second terminal of the memory element of the first memory cell, and a second terminal coupled to the source terminal of the first memory cell; and
a second transistor comprising a control terminal coupled to the control terminal of the first memory cell, a first terminal coupled to the second terminal of the memory element of the first memory cell, and a second terminal coupled to the source terminal of the first memory cell; and
the second memory cell comprises:
a memory element comprising a first terminal coupled to the first data terminal of the second memory cell, and a second terminal; and
a first transistor comprising a control terminal coupled to the control terminal of the second memory cell, a first terminal coupled to the second terminal of the memory element of the second memory cell, and a second terminal coupled to the source terminal of the second memory cell; and
a second transistor comprising a control terminal coupled to the control terminal of the second memory cell, a first terminal coupled to the second terminal of the memory element of the second memory cell, and a second terminal coupled to the source terminal of the second memory cell.

6. The memory device of claim 5, wherein the memory element of the first memory cell and the memory element of the second memory cell are magnetic tunnel junctions, and the first transistor and the second transistor of the first memory cell and the first transistor and the second transistor of the second memory cell are N-type transistors.

7. The memory device of claim 1, wherein:
the first memory cell further comprises a second data terminal;
the second memory cell further comprises a second data terminal; and
the memory device further comprises a second bit line coupled to the second data terminal of the first memory cell and the second data terminal of the second memory cell.

8. The memory device of claim 7, wherein:
the first memory cell comprises:
a first memory element comprising a first terminal coupled to the first data terminal of the first memory cell, and a second terminal;
a second memory element comprising a first terminal coupled to the second data terminal of the first memory cell, and a second terminal;
a first transistor comprising a control terminal coupled to the control terminal of the first memory cell, a first terminal coupled to the second terminal of the first memory element of the first memory cell, and a second terminal coupled to the source terminal of the first memory cell;
a second transistor comprising a control terminal coupled to the control terminal of the first memory cell, a first terminal coupled to the second terminal of the second memory element of the first memory cell, and a second terminal coupled to the source terminal of the first memory cell; and
a third transistor comprising a control terminal coupled to the control terminal of the first memory cell, a first terminal coupled to the first terminal of the first transistor of the first memory cell, and a second terminal coupled to the first terminal of the second transistor of the first memory cell; and
the second memory cell comprises:
a first memory element comprising a first terminal coupled to the first data terminal of the second memory cell, and a second terminal;
a second memory element comprising a first terminal coupled to the second data terminal of the second memory cell, and a second terminal;
a first transistor comprising a control terminal coupled to the control terminal of the second memory cell, a first terminal coupled to the second terminal of the first memory element of the second memory cell, and a second terminal coupled to the source terminal of the second memory cell;
a second transistor comprising a control terminal coupled to the control terminal of the second memory cell, a first terminal coupled to the second terminal of the second memory element of the second memory cell, and a second terminal coupled to the source terminal of the second memory cell; and
a third transistor comprising a control terminal coupled to the control terminal of the second memory cell, a first terminal coupled to the first terminal of the first transistor of the second memory cell, and a second terminal coupled to the first terminal of the second transistor of the second memory cell.

9. The memory device of claim 8, wherein the first memory element and the second memory element of the first memory cell and the first memory element and the second memory element of the second memory cell are magnetic tunnel junctions, and the first transistor, the second transistor and the third transistor of the first memory cell and the first transistor, the second transistor and the third transistor of the second memory cell are N-type transistors.

10. A memory device comprising:
a first source line formed along a first direction;
a second source line formed along the first direction, the second source line and the first source line being separated from each other;
a first bit line formed along the first direction;
a second bit line formed along the first direction;
a first memory cell comprising:
a first diffusion layer at least partially overlapping with the first bit line; and
a third diffusion layer at least partially overlapping with the first bit line;
a second memory cell comprising:
a second diffusion layer at least partially overlapping with the second bit line; and
a fourth diffusion layer at least partially overlapping with the second bit line;
a first bit line connection layer formed along a second direction and at least partially overlapping with the first diffusion layer and the second diffusion layer; and
a second bit line connection layer formed along a second direction and at least partially overlapping with the third diffusion layer and the fourth diffusion layer.

11. The memory device of claim 10, wherein:
the first memory cell further comprises:
a first polysilicon layer formed along the second direction and at least partially overlapping with the first source line and the first bit line;
a third polysilicon layer formed along the second direction and at least partially overlapping with the first source line and the first bit line, wherein the first diffusion layer is located between the first polysilicon layer and the third polysilicon layer;
a fifth polysilicon layer formed along the second direction and at least partially overlapping with the first source line and the first bit line, wherein the third diffusion layer is located between the third polysilicon layer and the fifth polysilicon layer;
a first magnetic tunnel junction overlapping with the first diffusion layer and the first bit line;
a third magnetic tunnel junction overlapping with the third diffusion layer and the first bit line;
a fifth diffusion layer at least partially overlapping with the first source line; and
a sixth diffusion layer at least partially overlapping with the first source line; and
the second memory cell further comprises:
a second polysilicon layer formed along the second direction and at least partially overlapping with the second source line and the second bit line;
a fourth polysilicon layer formed along the second direction and at least partially overlapping with the second source line and the second bit line, wherein the second diffusion layer is located between the second polysilicon layer and the fourth polysilicon layer;
a sixth polysilicon layer formed along the second direction and at least partially overlapping with the second source line and the second bit line, wherein the fourth diffusion layer is located between the fourth polysilicon layer and the sixth polysilicon layer;
a second magnetic tunnel junction overlapping with the second diffusion layer and the second bit line;
a fourth magnetic tunnel junction overlapping with the fourth diffusion layer and the second bit line;
a seventh diffusion layer at least partially overlapping with the second source line; and
an eighth diffusion layer at least partially overlapping with the second source line.

12. The memory device of claim 11, wherein:
the first source line and the second source line are formed by a same conductive layer;
the first bit line and the second bit line are formed by a same conductive layer;
the first bit line connection layer and the second bit line connection layer are formed by a same conductive layer;
the first polysilicon layer, the second polysilicon layer, the third polysilicon layer, the fourth polysilicon layer, the fifth polysilicon layer and the sixth polysilicon layer are formed by a same polysilicon layer; and
the first diffusion layer, the second diffusion layer, the third diffusion layer, the fourth diffusion layer, the fifth diffusion layer, the sixth diffusion layer, the seventh diffusion layer and the eighth diffusion layer are formed by a same diffusion layer.

13. The memory device of claim 11, wherein the first polysilicon layer, the second polysilicon layer, the third polysilicon layer, the fourth polysilicon layer, the fifth polysilicon layer and the sixth polysilicon layer are separated from each other.

14. The memory device of claim 11, further comprising:
a first contact overlapping with the fifth diffusion layer;
a second contact overlapping with the sixth diffusion layer;
a third contact overlapping with the seventh diffusion layer; and
a fourth contact overlapping with the eighth diffusion layer.

15. The memory device of claim 11, wherein:
the first memory cell further comprises a first via overlapping with the third diffusion layer and the third magnetic tunnel junction; and
the second memory cell further comprises a second via overlapping with the second diffusion layer and the second magnetic tunnel junction.

16. The memory device of claim 10, wherein the first bit line and the second bit line are separated from each other.

17. The memory device of claim 10, wherein the first direction is perpendicular to the second direction.
